(19) United States
(12) Patent Application Publication
(10) Pub. No.: US 2016/0042961 A1
(43) Pub. Date: Feb. 11, 2016

(54) ELECTRON BEAM PLASMA SOURCE WITH ROTATING CATHODE, BACKSIDE HELIUM COOLING AND LIQUID COOLED PEDESTAL FOR UNIFORM PLASMA GENERATION

(71) Applicant: APPLIED MATERIALS, INC., Santa Clara, CA (US)

(72) Inventors: Leonid Dorf, San Jose, CA (US); Hamid Tavassoli, Cupertino, CA (US); Kenneth S. Collins, San Jose, CA (US); Kartik Ramaswamy, San Jose, CA (US); James D. Carducci, Sunnyvale, CA (US); Shahid D. Rauf, Pleasanton, CA (US); Richard Fovell, San Jose, CA (US); Fernando M. Silveira, Livermore, CA (US); Mark Markovsky, San Jose, CA (US)

(21) Appl. No.: 14/453,023

(22) Filed: Aug. 6, 2014

(51) Int. Cl. H01L 21/3065; H01J 37/32

(52) U.S. Cl. CPC H01L 21/3065; H01J 37/32715; H01J 37/3244; H01J 37/3233

(57) ABSTRACT

A plasma reactor has an electron beam source as a plasma source and a rotation motor coupled to rotate the workpiece support about a rotation axis that is transverse to an emission path of said electron beam source.

### BACKGROUND

1. Technical Field

The disclosure relates to a plasma reactor for processing a workpiece such as a semiconductor wafer, in which the reactor includes an electron beam plasma source.

2. Background Discussion

A plasma reactor for processing a workpiece can employ an electron beam as a plasma source. The electron beam is produced as a planar sheet of electrons generally parallel to a plane of the workpiece. The electron beam is confined by providing a magnetic field parallel to the beam plane. The electron beam is directed to process gas in the plasma reactor to excite kinetic electrons and thereby produce plasma ions from the process gas. Such a plasma reactor can exhibit non-uniform distribution of processing results (e.g., distribution of etch rate across the surface of a workpiece) due to non-uniform distribution of electron density and/or kinetic energy within the electron beam. Such non-uniformities can be distributed along the direction of beam propagation and can also be distributed in a direction transverse to the beam propagation direction (i.e., across the beam width). Non-uniformity across the beam width can be due to a number of reasons including edge effects (in the electron beam source and in the processing chamber), E×B drift forces and J×B forces, and non-uniformity in the magnetic field confining the electron beam.

### SUMMARY

A plasma reactor for processing a workpiece, comprises a chamber and a workpiece support in the chamber having a workpiece support surface, the chamber comprising a ceiling facing the workpiece support surface; a process gas source having a gas flow path to an interior of the chamber; an electron beam source having an electron beam emission path overlying the workpiece support surface; and

a rotation motor coupled to the workpiece support, the workpiece support being rotatable about a rotation axis that is transverse to the electron beam emission path.

One embodiment further comprises a non-rotating outer housing surrounding the workpiece support and a bearing assembly between the non-rotating outer housing and the workpiece support.

One embodiment further comprises a first plurality of utility channels external of the workpiece support extending toward a bottom end of the workpiece support;

a second plurality of utility channels extending into the workpiece support; and a rotatable coupling assembly connecting individual ones of the first plurality utility channels with corresponding ones of the second plurality of utility channels. In a related embodiment, the first plurality of utility channels comprises plural sealed flow paths and plural electrical conductors; and the second plurality of utility channels comprises plural sealed flow paths and plural electrical conductors.

In one embodiment, the electron beam source produces a sheet-like electron beam propagating along the electron beam emission path and having a width of at least a diameter of the workpiece support surface.

One embodiment further comprises plural heaters in respective locations on the workpiece support, plural heater power supplies external of the workpiece support and connected via respective ones of the first and second pluralities of channels to the plural heater power supplies.

One embodiment further comprises plural sensors at respective locations on the workpiece support and a controller connected via respective ones of the first and second pluralities of channels to the sensors and to respective ones of the heater power supplies. In a related embodiment, the controller is programmed to control the heater power supplies in response to outputs received from the sensors.

In one embodiment, the rotation axis is perpendicular to the electron beam emission path. In one embodiment, the controller is connected to the rotation motor. In a related embodiment, the controller may be programmed to control dwell times at respective rotation angles of the rotation motor.

One embodiment further comprises a lift servo coupled to the workpiece support, and wherein the controller is connected to the lift servo.

One embodiment further comprises a backside gas supply, and wherein the workpiece support comprises back side gas outlets in the workpiece support surface, and wherein respective ones of the first and second pluralities of channels connect the backside gas outlets to the backside gas supply.

One embodiment further comprises a coolant supply, and wherein the workpiece support comprises internal coolant passages, and wherein respective ones of the first and second pluralities of channels connect the internal coolant passages to the coolant supply.

In another aspect, a method of processing a workpiece comprises providing a process gas over a surface of the workpiece while directing an electron beam to the process gas and while rotating the workpiece. In one embodiment, the method further comprises applying a backside gas to a backside of the workpiece and flowing a coolant through coolant passages underling the workpiece while rotating the workpiece.

### BRIEF DESCRIPTION OF THE DRAWINGS

So that the manner in which the exemplary embodiments of the present invention are attained can be understood in detail, a more particular description of the invention summarized above is given by reference to the embodiments thereof which are illustrated in the appended drawings. It is to be appreciated that certain well known processes are not discussed herein in order to not obscure the invention.

FIG. 1A is a simplified cut-away elevational view of one embodiment.

FIG. 1B is a plan view corresponding to FIG. 1A.

FIG. 2 is a simplified enlarged view of a portion of FIG. 1A.

FIG. 3 is a simplified plan view corresponding to FIG. 2.

FIG. 4 depicts an enlarged view of the workpiece support pedestal of FIG. 2.

FIG. 5 depicts one embodiment.

FIG. 6 is a side view of a rotational coupler that can be employed in the embodiment of FIG. 5.

FIG. 7 is a partial cross-sectional view taken along lines 7-7 of FIG. 6.

FIG. 8 is a side view of another rotational coupler that can be employed in the embodiment of FIG. 5.

FIG. 8A is an enlarged view of a portion of FIG. 8.

FIG. 9 is a partial cross-sectional view taken along lines 9-9 of FIG. 8.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

In a plasma reactor having an electron beam plasma source, non-uniformity in process rate distribution due to the electron beam is overcome by rotating the workpiece support pedestal about the workpiece axis of symmetry during processing. Rotation can be realized using a variety of algorithms, such as back and forth, all in the same direction, stop and go, etc. The dwell time at each azimuthal angle can be controlled by such algorithm. The workpiece support pedestal in an etch chamber is typically a biased electrode (cathode), which requires complicated internal structure that includes liquid cooling, back-side Helium gas delivery, RF delivery, DC/AC delivery for electric heaters, thermocouples, fiberoptics, and other diagnostic instrumentation. Rotation of such an internal structure achieved in embodiments described below.

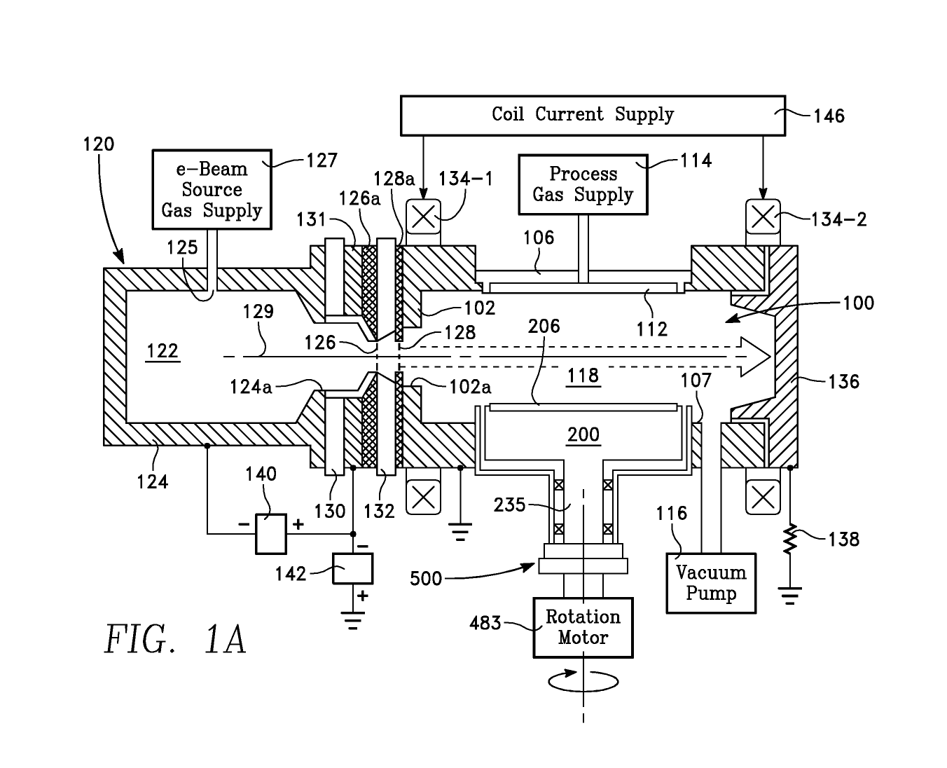

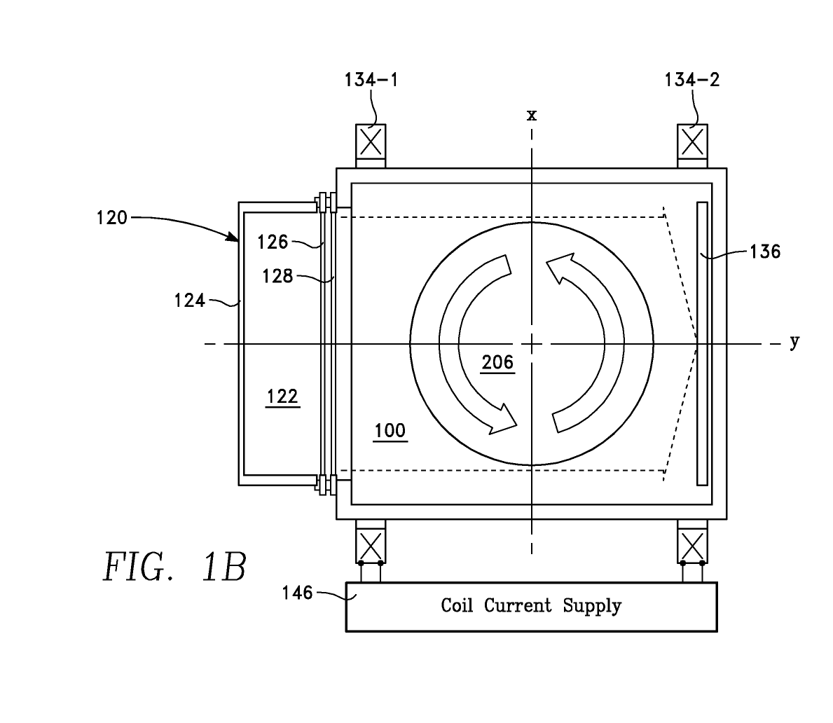

Referring to FIGS. 1A and 1B, a plasma reactor has an electron beam generator as a plasma source. The reactor includes a processing chamber 100 enclosed by a cylindrical side wall 102, a floor 107 and a ceiling 106. A workpiece support pedestal 200 supports a workpiece 206, such as a semiconductor wafer, the pedestal 200 being movable in the axial (e.g., vertical) direction. A gas distribution plate 112 is integrated with or mounted on the ceiling 106, and receives process gas from a process gas supply 114. A vacuum pump 116 evacuates the processing chamber 100 through a passage in the floor 107. A processing region 118 is defined between the workpiece support pedestal 200 and the gas distribution plate 112. Within the processing region 118, the process gas is ionized to produce a plasma for processing of the workpiece 206.

The plasma is generated in the processing region 118 by an electron beam from an electron beam source 120. The electron beam source 120 includes a plasma generation chamber 122 spaced from the processing chamber 100 and having a conductive (or partially conductive) enclosure 124. The conductive enclosure 124 has a gas inlet 125. An electron beam source gas supply 127 is coupled to the gas inlet 125. The conductive enclosure 124 has an opening 124a facing the processing region 118 through an opening 102a in the side wall 102 of the processing chamber 100.

The electron beam source 120, in one embodiment, includes an extraction grid 126 adjacent the opening 124a and the plasma generation chamber 122, and an acceleration grid 128 adjacent the extraction grid 126 and facing the processing region 118. The extraction grid 126 and the acceleration grid 128 may each be formed as either a conductive mesh or a slotted electrode, for example, and are herein referred to generically as grids. Electrical contact to the extraction grid 126 is provided by a conductive ring 126a surrounding the extraction grid. Electrical contact to the acceleration grid 128 is provided by a conductive ring 128a surrounding the acceleration grid 128. The extraction grid 126 and the acceleration grid 128 are mounted with insulators 130, 132, respectively, so as to be electrically insulated from one another and from the conductive enclosure 124. However, the acceleration grid 128 is in electrical contact with the side wall 102 of the chamber 100. The openings 124a and 102a and the extraction and acceleration grids 126, 128 are mutually congruent, generally, and define a thin wide flow path for an electron beam into the processing region 118. The width of the flow path is about the diameter of the workpiece 206 (e.g., 100-400 mm) while the height of the flow path is less than about two inches. The flow path of the electron beam is generally parallel to an in-chamber beam axis 129 that is generally parallel with the ceiling 106 and generally parallel with a plane of the workpiece 206.

A pair of electromagnets 134-1 and 134-2 are adjacent opposite ends of the chamber 100, the electromagnet 134-1 being near the electron beam source 120. The two electromagnets 134-1 and 134-2 produce a magnetic field parallel to the electron beam path along the in-chamber beam axis 129. The electron beam flows across the processing region 118 over the workpiece 206, and is absorbed at the opposite end of the processing region 118 by a beam dump 136. The beam dump 136 is a conductive body having a shape adapted to capture the wide thin electron beam. The beam dump 136 may be coupled to ground through a shunt resistor 138.

The electron beam source 120 may produce plasma within the plasma generation chamber 122 by a power source coupled to a source power applicator in or adjacent the plasma generation chamber 122. The density of plasma produced by the electron beam in the processing region 118 may be controlled by controlling the power level of the power source or the electron beam source, for example. Alternatively or in addition, the plasma density in the processing region 118 may be controlled by controlling the gas flow rate from the electron beam source gas supply 127 to the gas inlet 125.

In one embodiment, the electron beam source 120 is an inductively coupled plasma source, in which case the source power applicator is a coil antenna and the power source is an RF power generator. In another embodiment, the electron beam source 120 is a capacitively coupled plasma source, in which case the source power applicator is an electrode or a wall of the plasma generation chamber 122 and the power source is an RF power generator. In yet another embodiment, the electron beam source 120 is a D.C. discharge plasma source, in which case the source power applicator is a wall of the plasma generation chamber 122 and the power source is a D.C. voltage supply 140. It is this latter embodiment that is depicted in the drawings of FIGS. 1A and 1B, which will now be discussed in detail. Alternatively, the electron beam source 120 may be a microwave plasma source.

A negative terminal of the D.C. voltage supply 140 is coupled to the conductive enclosure 124, and a positive terminal of the D.C. voltage supply 140 is coupled to the extraction grid 126. In turn, a negative terminal of an electron beam acceleration voltage supply 142 is coupled to the extraction grid 126, and a positive terminal of the voltage supply 142 is connected to ground. In one embodiment the acceleration grid 128 is grounded. A coil current supply 146 is coupled to the electromagnets 134-1 and 134-2. Electrons are extracted from the plasma in the plasma generation chamber 122 through the extraction grid 126 and the acceleration grid 128 to produce an electron beam that flows into the processing chamber 100. Electrons are accelerated to energies corresponding to the voltage provided by the acceleration voltage supply 142.

A chiller plate 131 may be interposed between the ceramic insulator 130 and the extraction grid 126. The chiller plate 131 may be metallic and include internal coolant flow passages (not illustrated). In one embodiment, the chiller plate 131 contacts the extraction grid 126, and the discharge voltage supply 140 and the acceleration voltage supply 142 may be coupled to the extraction grid 126 by connection to the chiller plate 131, as shown in FIG. 1A.

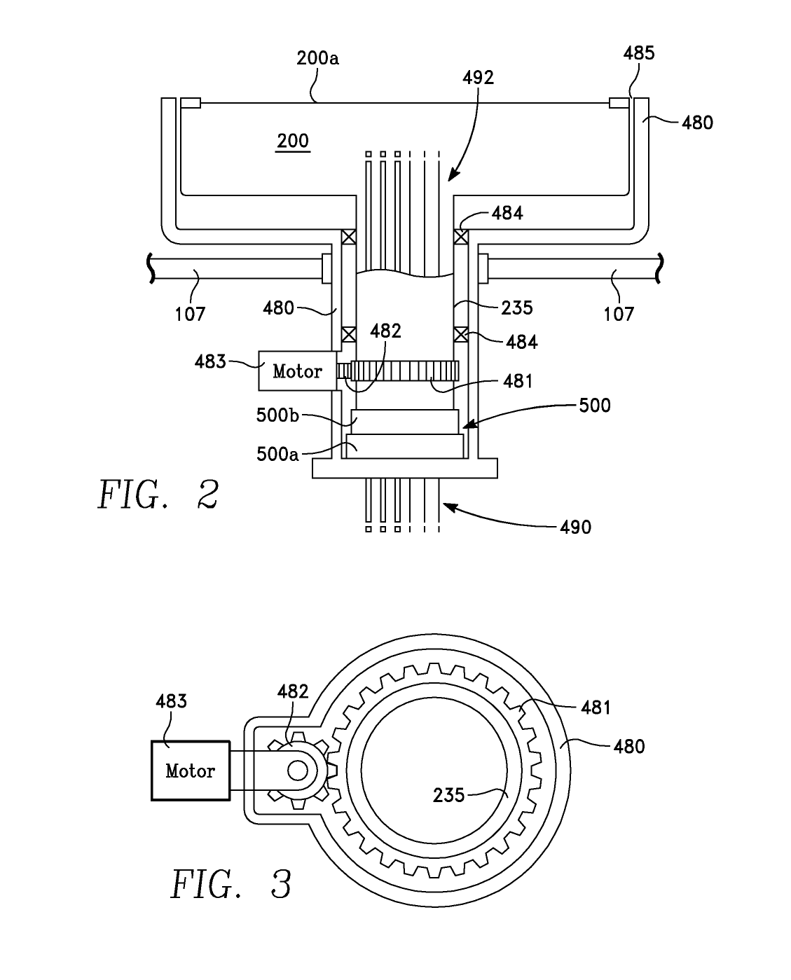

Referring to FIGS. 2 and 3, the workpiece support pedestal 200 is rotated about its axis of symmetry and is surrounded by a non-rotating outer housing 480. Rotation of the workpiece support pedestal is performed by an assembly including an outer gear 481 on the side of the workpiece support pedestal 200, a drive gear 482 engaged with the outer gear 481, and an electric motor 483 connected to the drive gear 482. Both the drive gear 482 and the electric motor 483 may be fixed with respect to the outer housing 480. Bearings 484 support a stem 235 of the workpiece support pedestal 200 and center it with respect to the outer housing 480, while maintaining an annular gap 485 between the outer housing 480 and the workpiece support pedestal 200.

As indicated in FIG. 2, various non-rotating channels 490 (such as electrical conductors and gas/liquid conduits) below the workpiece support pedestal 200 are connected to corresponding rotating channels 492 extending through the stem 235 of the rotating workpiece support pedestal 200 through a rotatable coupling assembly 500. The rotatable coupling assembly 500 includes a non-rotating portion 500a connected to the non-rotating channels 490 and a rotating portion 500b connected to the channels 492 inside the stem 235 of the workpiece support pedestal 200.

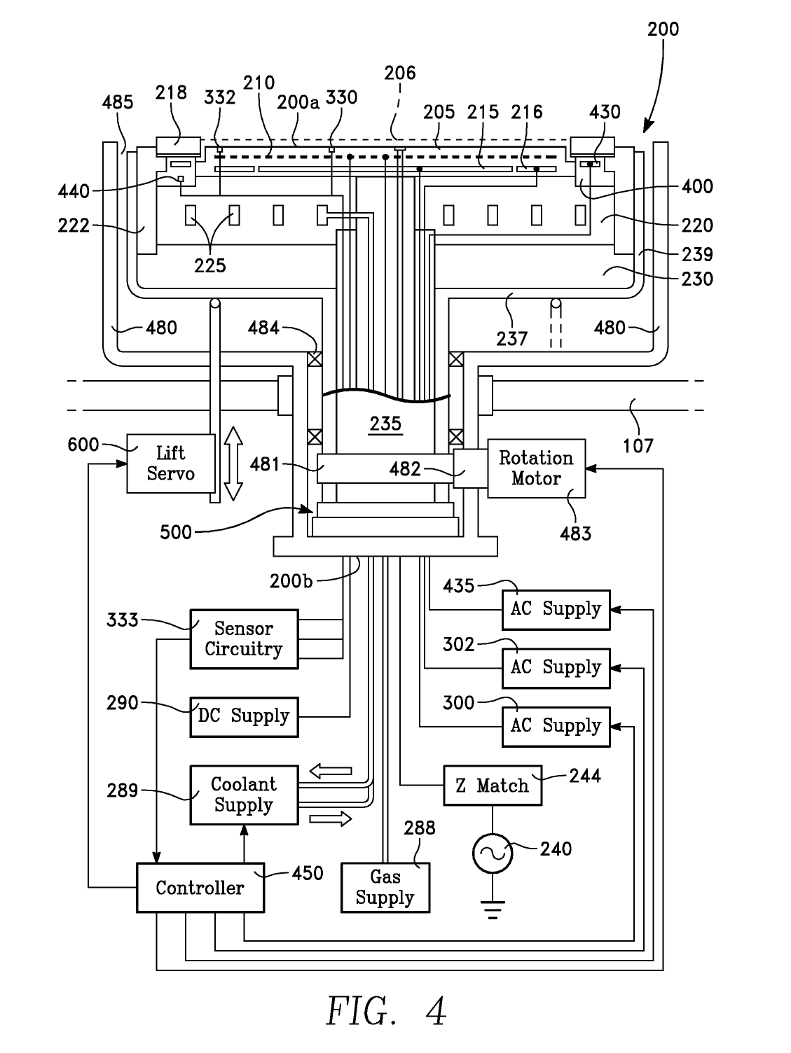

Referring to FIG. 4, the workpiece support pedestal 200 has a top workpiece support surface 200a and a bottom end 200b below the floor 107, and the stem 235 extending axially upwardly from the bottom end 200b and through the floor 107. The pedestal 200 includes a disk-shaped insulating puck 205 forming the top workpiece support surface 200a. The puck 205 contains an electrostatic chucking (ESC) electrode 210 close to the workpiece support surface 200a. The puck 205 also contains inner and outer heater elements 215, 216, respectively.

Underlying the puck 205 is a disk-shaped metal base 220, which may be formed of aluminum. The workpiece support surface 200a is the top surface of the puck 205 for supporting a workpiece 206 such as a semiconductor wafer. Internal coolant passages 225 are provided in the metal base 220. A disk-shaped insulator layer 230 underlies the metal base 220, and may be formed of a silicon dioxide or silicon nitride material, for example.

A cylindrical pedestal side wall 239 surrounds the insulator layer 230, the metal base 220 and the puck 205. In one embodiment, a conductive support dish 237 underlies the insulator layer 230.

A process ring 218 overlies the edge of the puck 205. The process ring 218 may be formed of a semiconductor material. A thermally conductive ring 400 may be disposed between the process ring 218 and the metal base 220. An insulation ring 222 provides electrical insulation between the metal base 220 and the pedestal side wall 239.

An RF bias power generator 240 is coupled through an impedance match 244 to the ESC electrode 210. Alternatively, the RF bias power generator 240 may be coupled to the metal base 220.

A backside gas supply 288 is connected via a conduit in the stem 235 to backside gas orifices (not illustrated) in the workpiece support surface 200a. The backside gas supply may contain helium. Pressure of the gas in the interface between the backside of the workpiece 206 and the workpiece support surface 200a affects thermal conductivity, for controlling workpiece temperature. A coolant supply 289 is coupled to the internal coolant passages 225 via liquid-carrying conduits. A D. C. workpiece clamping voltage source 290 is coupled to the electrostatic chucking (ESC) electrode 210 via an electrical conductor. The inner and outer heater elements 215 and 216 are connected to respective heater power supplies 300 and 302 via respective electrical conductors.

In one embodiment, a lift servo 600 provides axial height adjustment of the workpiece support pedestal 200 to control the distance between the workpiece support surface 200a and the ceiling 106. Such adjustment can be used to affect process rate distribution over the workpiece 206.

In one embodiment, an inner zone temperature sensor 330 extends through an opening in the workpiece support surface 200a and an outer zone temperature sensor 332 extends through another opening in the workpiece support surface 200a. Electrical (or optical) connection from the temperature sensors 330, 332 to sensor circuitry 333 is provided via respective electrical (or optical) conductors extending through the stem 235. The temperature of the process ring 218 may be controlled independently of the temperature of the workpiece 206, by providing a separately controlled heater element 430 within the thermally conductive ring 400. The heater element 430 may receive electrical power from a heater power supply 435 through insulated conductors extending through the stem 235 and the metal base 220. In addition, a temperature sensor 440 may be coupled to or provided inside of the thermally conductive ring 400 and coupled to the sensor circuitry 333 respective conductors. A controller 450 senses the workpiece temperature and the process ring temperature through the sensor circuitry 333. The controller 450 governs the flow rate and/or temperature of the coolant supply 289, and the levels of electric power output by the heater power supplies 300, 302 and 435, separately, so as to maintain the workpiece 206 at a target workpiece temperature while maintaining the process ring 218 at a target process ring temperature, in the manner of a feedback control loop. The workpiece and process ring target temperatures are independently selected by programming the controller 450. The controller 450 may also govern the lift servo 600.

The rotatable coupling assembly 500 of FIG. 2 may be implemented as an assembly of individual rotatable couplings, including rotatable electrical couplings for the electrical conductors and rotatable sealed couplings for the gas and liquid-carrying conduits.

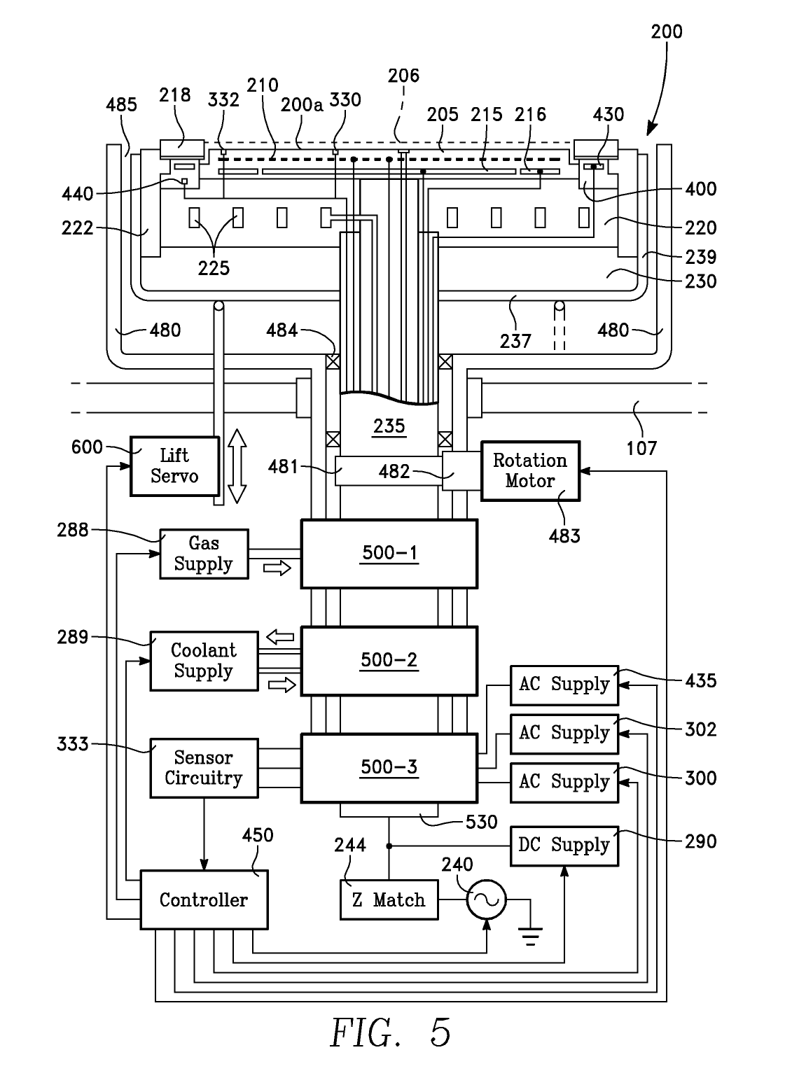

In an embodiment depicted in FIG. 5, a rotatable gas coupling 500-1 is connected between a rotating conduit inside the rotating stem 235 and a non-rotating conduit from the gas supply 288. A rotatable liquid coupling 500-2 is connected between rotating conduits inside the rotating stem 235 and non-rotating conduits from the coolant supply 289. A rotatable electrical coupling 500-3 is connected between rotating conductors inside the stem 235 and non-rotating conductors from the heater power supplies 300, 302 and 435. A slip ring electrical coupler 530 is centered relative to the axis of rotation about which the electric motor 483 rotates the pedestal 200 and stem 235. A rotating portion of the slip ring electrical coupler 530 is connected via a conductor inside the stem 235 to an electrode in the pedestal 200 (e.g., the ESC electrode 210). A non-rotating portion of the slip ring electrical coupler 530 is connected to an electrical source such as the RF bias power generator 240, the impedance match 244 and/or the D. C. workpiece clamping voltage source 290.

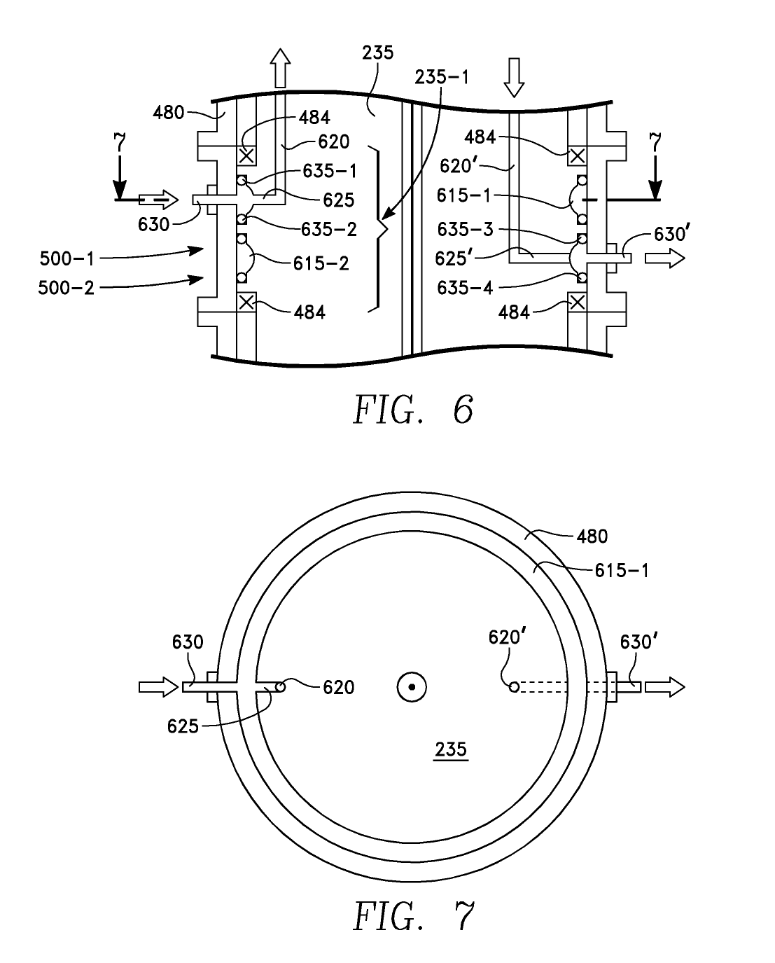

FIGS. 6 and 7 depict a gas or liquid rotational coupler (e.g., which may be embodied in one or both of the couplers 500-1 or 500-2 of FIG. 5). The coupler of FIGS. 6 and 7 includes elements in one section 235-1 of the stem 235 and elements in one section of the non-rotating housing 480, which elements will now be described. A manifold 615-1 extends around the circumference of the section 235-1 of the stem 235. An axial conduit 620 inside the stem 235 joins a radial conduit 625 whose outer end connects to the manifold 615-1. A radial conduit 630 inside the non-rotating housing 480 has a radially inner end facing and open to the manifold 615-1. Gas flows from the radial conduit 630 and across a stem-to-housing interface between the housing 480 and the stem 235 and into the radial conduit 625. Leakage into the interface is blocked by a pair of O-rings 635-1 and 635-2 wrapped around the stem 235 above and below the manifold 615-1, respectively.

The radial conduit 630, which is non-rotating, is thus connected to internal conduits in the rotating stem 235. Optionally, a second radial conduit 630′ (which is non-rotating) may be connected in similar manner to other internal conduits in the rotating stem 235, as will now be described. A second manifold 615-2 extends around the circumference of the section 235-1 of the stem 235. An axial conduit 620′ inside the stem 235 joins a radial conduit 625′ whose outer end connects to the manifold 615-2. A radial conduit 630′ inside the non-rotating housing 480 has a radially inner end facing and open to the manifold 615-2. Gas (or liquid) flows from the radial conduit 630′ and across the stem-to-housing interface and into the radial conduit 625′. Leakage into the interface is blocked by a pair of O-rings 635-3 and 635-4 wrapped around the stem 235 above and below the manifold 615-2, respectively. In one embodiment, the radial conduit 630 may be a supply channel while the radial conduit 630′ may be a return channel. While FIGS. 6 and 7 depict coupling of two independent conduits 630 and 630′, a larger number of conduits may be accommodated by distributing them azimuthally around the stem 235 at different axial heights.

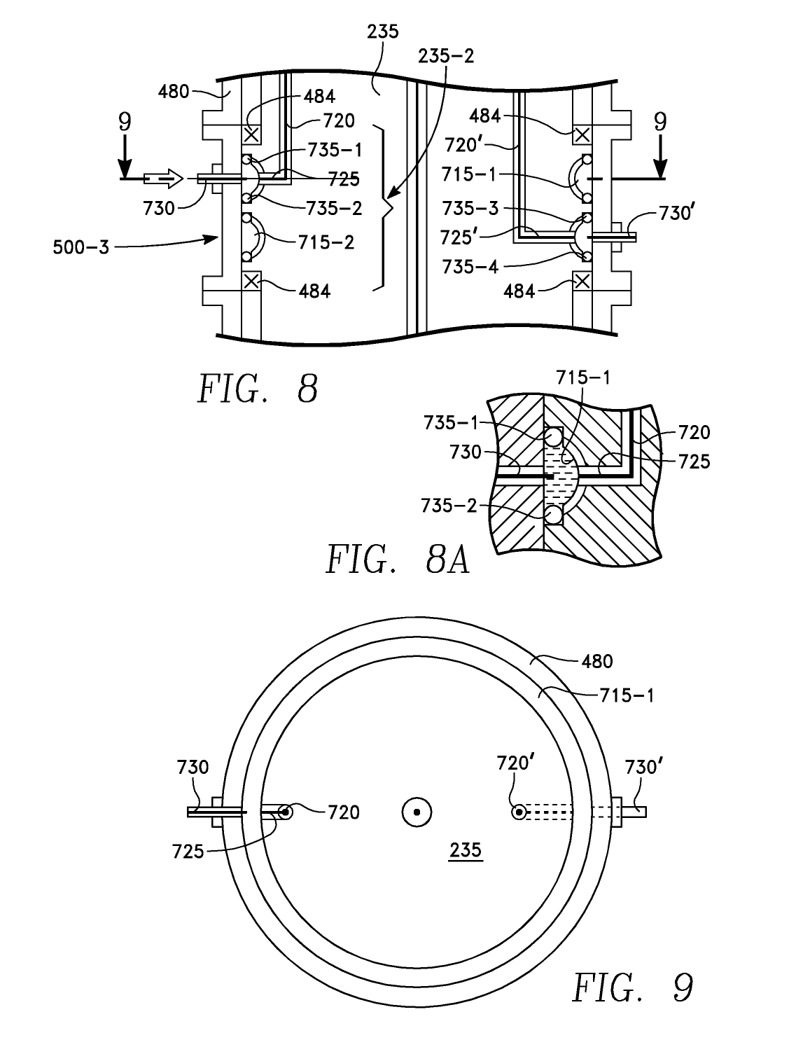

FIGS. 8, 8A and 9 depict an electrical rotational coupler (e.g., which may be embodied in the coupler 500-3 of FIG. 5). The coupler of FIGS. 8 and 9 includes elements in one section 235-2 of the stem 235 and elements in one section of the non-rotating housing 480, which elements will now be described. A manifold 715-1 containing a liquid conductor (e.g., Mercury) extends around the circumference of the section 235-2 of the stem 235. An axial conductor 720 inside the stem 235 joins a radial conductor 725 whose outer end connects to the manifold 715-1. The axial conductor 720 and the radial conductor 725 are inside the stem 235 and insulated from the stem 235. The manifold 715-1 may be electrically insulated from other portions of the stem 235. A radial conductor 730 inside (and insulated from) the housing 480 has a radially inner end extending out of the housing 480 and into the Mercury in the manifold 715-1 so as to be immersed in the Mercury. As the stem 235 rotates, the immersed portion of the radial conductor 730 moves through the Mercury in the manifold 715-1 and provides electrical contact. Electrical current flows from the radial conductor 730 and across a stem-to-housing interface (between the housing 480 and the stem 235), through the Mercury in the manifold 715-1 and to the radial conductor 725. Leakage into the stem-to-housing interface is blocked by a pair of O-rings 735-1 and 735-2 wrapped around the stem 235 above and below the manifold 715-1, respectively.

The non-rotating conductor 730 is thus electrically connected to internal conductors in the rotating stem 235. Optionally, a second non-rotating conductor 730′ may be connected in similar manner to other internal conductors in the rotating stem 235, as will now be described. A second manifold 715-2 containing a liquid conductor (e.g., Mercury) extends around the circumference of the section 235-2 of the stem 235. An axial conductor 720′ inside the stem 235 joins a radial conductor 725′ whose outer end connects to the manifold 715-2. The axial conductor 720′ and the radial conductor 725′ are inside the stem 235 and insulated from the stem 235. The manifold 715-2 may be electrically insulated from other portions of the stem 235. A radial conductor 730′ inside (and insulated from) the housing 480 has a radially inner end extending out of the housing 480 and into the Mercury in the manifold 715-2 so as to be immersed in the Mercury. As the stem 235 rotates, the immersed portion of the radial conductor 730′ moves through the Mercury in the manifold 715-2 and provides electrical contact. Leakage into the stem-to-housing interface is blocked by a pair of O-rings 735-3 and 735-4 wrapped around the stem 235 above and below the manifold 715-2, respectively. While FIGS. 8 and 9 depict coupling of two independent conductors 730 and 730′, a larger number of conductors may be accommodated.

### Advantages

The foregoing embodiments facilitate processing of a workpiece using an electron beam plasma source in which the non-uniformities in azimuthal distribution of plasma ion density inherent in the electron beam are averaged out by rotation of the workpiece support pedestal about the axis of symmetry of the workpiece (e.g., a wafer), while simultaneously facilitating communication through the rotating pedestal of sensor outputs (e.g., thermocouple outputs), heater currents, liquid coolant, back-side Helium gas delivery, RF power delivery, a D. C. (ESC) voltage, AC currents for electric heaters, thermocouples, fiberoptics, and diagnostic instrumentation generally. As noted previously herein, embodiments can include a feedback control loop responsive to plural sensor outputs for controlling heater currents to regulate workpiece temperature.

While the foregoing is directed to embodiments of the present invention, other and further embodiments of the invention may be devised without departing from the basic scope thereof, and the scope thereof is determined by the claims that follow.

What is claimed is:

1. A plasma reactor for processing a workpiece, comprising:
a chamber and a workpiece support in said chamber having a workpiece support surface, said chamber comprising a ceiling facing said workpiece support surface;
a process gas source having a gas flow path to an interior of said chamber;
an electron beam source having an electron beam emission path overlying said workpiece support surface; and
a rotation motor coupled to said workpiece support, said workpiece support being rotatable about a rotation axis that is transverse to said electron beam emission path.

2. The plasma reactor of claim 1 further comprising a non-rotating outer housing surrounding said workpiece support and a bearing assembly between said non-rotating outer housing and said workpiece support.

3. The plasma reactor of claim 2 further comprising:
a first plurality of utility channels external of said workpiece support extending toward said workpiece support;
a second plurality of utility channels extending into said workpiece support; and
a rotatable coupling assembly connecting individual ones of said first plurality utility channels with corresponding ones of said second plurality of utility channels.

4. The plasma reactor of claim 3 wherein:
said first plurality of utility channels comprises plural sealed flow paths and plural electrical conductors; and
said second plurality of utility channels comprises plural sealed flow paths and plural electrical conductors.

5. The plasma reactor of claim 3 wherein said electron beam source produces a sheet-like electron beam propagating along said electron beam emission path and having a width of at least a diameter of said workpiece support surface.

6. The plasma reactor of claim 4 further comprising plural heaters in respective locations on said workpiece support, plural heater power supplies external of said workpiece support and connected via respective ones of said first and second pluralities of channels to said plural heater power supplies.

7. The plasma reactor of claim 6 further comprising plural sensors at respective locations on said workpiece support and a controller connected via respective ones of said first and second pluralities of channels to said sensors and to respective ones of said heater power supplies.

8. The plasma reactor of claim 7 wherein said controller is programmed to control said heater power supplies in response to outputs received from said sensors.

9. The plasma reactor of claim 1 wherein said rotation axis is perpendicular to said electron beam emission path.

10. The plasma reactor of claim 7 wherein said controller is connected to said rotation motor.

11. The plasma reactor of claim 10 wherein said controller is programmed to control dwell times at respective rotation angles of said rotation motor.

12. The plasma reactor of claim 10 further comprising a lift servo coupled to said workpiece support, and wherein said controller is connected to said lift servo.

13. The plasma reactor of claim 3 further comprising a backside gas supply, and wherein said workpiece support comprises back side gas outlets in said workpiece support surface, and wherein respective ones of said first and second pluralities of utility channels connect said backside gas outlets to said backside gas supply.

14. The plasma reactor of claim 13 further comprising a coolant supply, and wherein said workpiece support comprises internal coolant passages, and wherein respective ones of said first and second pluralities of utility channels connect said internal coolant passages to said coolant supply.

15. A plasma reactor comprising a workpiece support, an electron beam source and a rotation motor coupled to rotate said workpiece support about a rotation axis that is transverse to an emission path of said electron beam source.

16. The plasma reactor of claim 15 further comprising a non-rotating outer housing surrounding said workpiece support and a bearing assembly between said non-rotating outer housing and said workpiece support.

17. The plasma reactor of claim 16 further comprising:
a first plurality of utility channels external of said workpiece support extending toward said workpiece support;
a second plurality of utility channels extending into said workpiece support; and
a rotatable coupling assembly connecting individual ones of said first plurality utility channels with corresponding ones of said second plurality of utility channels.

18. The plasma reactor of claim 17 wherein:
said first plurality of utility channels comprises plural sealed flow paths and plural electrical conductors; and
said second plurality of utility channels comprises plural sealed flow paths and plural electrical conductors.

19. A method of processing a workpiece, comprising:
providing a process gas over a surface of the workpiece while directing an electron beam to said process gas and while rotating said workpiece.

20. The method of claim 19 further comprising applying a backside gas to a backside of said workpiece and flowing a coolant through coolant passages underling said workpiece while rotating said workpiece.
